(19) United States
(12) Patent Application Publication
(10) Pub. No.: US 2019/0189743 A1
(43) Pub. Date: Jun. 20, 2019

(54) Planar Field Effect Transistor

(71) Applicant: Infineon Technologies AG, Neubiberg (DE)

(72) Inventors: Andreas Meiser, Sauerlach (DE); Grzegorz Kozlowski, Munich (DE)

(21) Appl. No.: 16/220,592

(22) Filed: Dec. 14, 2018

(30) Foreign Application Priority Data
Dec. 15, 2017 (DE) 102017130213.1

(51) Int. Cl. H01L 29/08; H01L 29/735; H01L 29/78; H01L 29/40; H01L 29/06; H01L 29/423; H01L 29/10

(52) U.S. Cl. CPC H01L 29/0847; H01L 29/0821; H01L 29/735; H01L 29/1095; H01L 29/402; H01L 29/0653; H01L 29/4238; H01L 29/7835

(57) ABSTRACT

The disclosure relates to a planar field effect transistor. The planar field effect transistor includes a drain extension region between a channel region and a drain terminal at a first surface of a semiconductor body. The planar field effect transistor also includes a first electrode part and a second electrode part laterally spaced apart from the first electrode part. The first electrode part is arranged as a gate electrode above the channel region. The second electrode part is arranged above the drain extension region and is electrically isolated from the first electrode part.

### TECHNICAL FIELD

The application relates to a planar field effect transistor.

### BACKGROUND

In semiconductor components comprising field effect transistors, a multiplicity of field effect transistor cells are typically connected in parallel in order to realize a desired current-carrying capacity in a power semiconductor component. In circuit applications such as DC-DC converters, for instance, the transistors are optimized for example so as to minimize losses that occur in each switching cycle. Different switching states are undergone during each cycle, wherein different loss portions arise in each switching phase, which loss portions can be increased or decreased by specific transistor parameters. In the case of large load currents, by way of example, the transistor resistance in the on state Rdson is a dominant parameter of the circuit application, whereas switching losses as a result of capacitances come to the fore in the medium and low current ranges.

It is desirable to reduce the switching losses of planar field effect transistors in order thereby to improve the efficiency of a circuit arrangement realized with the field effect transistors.

### SUMMARY

The present disclosure relates to a planar field effect transistor. The planar field effect transistor comprises a drain extension region between a channel region and a drain terminal at a first surface of a semiconductor body. The planar field effect transistor additionally comprises a first electrode part and a second electrode part, which are spaced apart laterally from one another, wherein the first electrode part is arranged as a gate electrode above the channel region and the second electrode part is arranged above the drain extension region and is electrically isolated from the first electrode part. The electrical isolation between first electrode part and second electrode part makes it possible to reduce the gate capacitance Cg by virtue of the second electrode part being embodied as a field plate and being electrically connected to a reference potential, for example. The gate capacitance Cg comprises a gate-to-drain capacitance Cgd and also a gate-to-source capacitance Cgs. The first and second electrode part are for example spaced-apart parts of the same wiring plane from which laterally spaced-apart parts such as, for instance, conductor tracks or electrodes are obtained by patterning, e.g. lithographic patterning.

In accordance with one embodiment, the second electrode part is electrically connected to a source terminal and thus does not contribute to the gate capacitance Cg.

In accordance with one embodiment, the planar field effect transistor is a lateral power semiconductor component in which a body region and a source region are electrically short-circuited. In the case of the lateral power semiconductor component, a channel region forms in a part of the body region at the first surface which overlaps a gate dielectric and the first electrode part acting as gate electrode, the conductivity of which channel region can be controlled by applying a suitable voltage to the first electrode part. Along the channel region it is thus possible to control a channel current that flows in a lateral direction parallel to the first surface. In a normally off n-channel FET, i.e. an enhancement-mode n-channel FET, by way of example, a conductive channel arises if a positive voltage between the gate terminal G and the source terminal S exceeds a threshold voltage Vth. In this case, the channel transitions to a blocking state again if the gate voltage falls below the threshold voltage, e.g. at a gate voltage of 0V.

In accordance with one embodiment, the drain extension region is suitable for blocking a drain-to-source voltage in a range of 5V to 200V. The desired voltage blocking range can be set by means of a suitable dimensioning and doping of the drain extension region. The planar field effect transistor can thus be used for example in circuit applications such as DC-DC converters. In order also to realize a desired current-carrying capacity, the planar field effect transistor can be constructed from a multiplicity of parallel-connected planar field effect transistor cells. The parallel-connected planar field effect transistor cells can be for example field effect transistor cells embodied in the form of a strip or strip segment. It goes without saying that the field effect transistor cell, can also have any other form desired, e.g. be circular, elliptic, polygonal such as octahedral, for example.

In accordance with one embodiment, the first electrode part and the second electrode part are different parts of a patterned electrode layer. The electrode layer can be a conductive layer such as, for instance, a metal layer, a metal silicide layer, a metal alloy or else a highly doped semiconductor layer or a combination of these materials. The electrode layer can be for example a wiring layer which can act as a conductor track or an electrode after patterning in other component regions. It goes without saying that the electrode layer can also be an electrode layer between a first wiring plane and the first semiconductor surface.

In accordance with one embodiment, the planar field effect transistor additionally comprises a deep body region, which is electrically connected to the source terminal and extends laterally below the drain extension region, wherein an extent of the deep body region in a first lateral direction and an extent of the drain extension region in the first lateral direction at least partly overlap. The first lateral direction is for example a channel length direction of the channel region perpendicular to a channel width direction. The channel length direction extends for example along a direction from the source terminal to the drain terminal of the planar field effect transistor. The partial overlap has a positive effect on the blocking capability of the planar field effect transistor on account of the compensation principle or RESURF (REduced SURface Field) principle. The extent of the deep body region in the first lateral direction and an extent of the first electrode part acting as a gate electrode in the first lateral direction can for example likewise overlap.

In accordance with one embodiment, the extent of the deep body region in the first lateral direction and an extent of the second electrode part in the first lateral direction at least partly overlap.

In accordance with one embodiment, the deep body region comprises laterally adjacent first and second body partial regions, and a dopant dose in the first body partial region located laterally closer to the drain terminal is lower than that in the second body partial region. It is thereby possible to achieve a further improvement in the on resistance Rdson and the drain-to-source blocking capability, i.e. a drain-to-source breakdown voltage.

In accordance with one embodiment, the planar field effect transistor comprises a gate dielectric between the first electrode part and the channel region, and a further dielectric between the first electrode part and the drain extension region, wherein a thickness of the further dielectric is greater than a thickness of the gate dielectric and the gate dielectric adjoins the further dielectric in the direction of the drain terminal. As a result of the increased thickness of the dielectric, it is possible to further reduce the electric fields at the first surface, as a result of which it is possible to achieve a further improvement in the breakdown behavior of the planar field effect transistor.

In accordance with a further embodiment, the further dielectric comprises an STI dielectric, Shallow Trench Isolation dielectric.

In accordance with a further embodiment, the further dielectric between the STI dielectric and the gate dielectric additionally comprises a planar dielectric that is thicker than the gate dielectric and at the first surface adjoins a top side of a part of the drain extension region. As a result of the increased thickness of the planar dielectric, it is possible to further reduce the electric fields at the first surface, as a result of which it is possible to achieve a further improvement in the breakdown behavior of the planar field effect transistor.

In accordance with a further embodiment, a part of the gate dielectric at the first surface adjoins a top side of a part of the drain extension region.

In accordance with a further embodiment, the further dielectric corresponds to or comprises a LOCOS oxide, Local Oxidation of Silicon oxide.

In accordance with a further embodiment, the further dielectric is a planar dielectric, the underside of which transitions into an underside of the gate dielectric without any steps, and the top side of which transitions into a top side of the gate dielectric via a step directed toward the first surface. It is thereby possible to further reduce the electric fields at the first surface, as a result of which it is possible to achieve a further improvement in the breakdown behavior of the planar field effect transistor.

In accordance with a further embodiment, a thickness of the further dielectric increases in the direction of the drain terminal. An underside of the further dielectric extends parallel to the first surface, and the second electrode part is arranged on a top side region of the further dielectric that is oblique with respect to the first surface. By this means, too, it is possible to further reduce the electric fields at the first surface, as a result of which it is possible to achieve a further improvement in the breakdown behavior of the planar field effect transistor.

In accordance with a further embodiment, the second electrode part is electrically connected via a contact to a field plate arranged above the second electrode part, and the field plate extends in a lateral direction further to the drain terminal than the second electrode part. It is thereby possible to further improve the electric field profile in the drift region and to achieve a higher drain-to-source blocking capacity. The field plate can be for example a part of a first patterned metallization plane.

In accordance with one embodiment, the planar field effect transistor additionally comprises a third electrode part above the drain extension region, wherein the second electrode part is arranged laterally between the third electrode part and the first electrode part, and the third electrode part is electrically connected to the second electrode part via the field plate. The lateral separation of the drain-side field plates makes it possible to achieve a further improvement in the electric field profile in the drift region and thus to improve the drain-to-source blocking capacity.

In accordance with one embodiment, the drain extension region comprises laterally adjacent first and second drain extension subregions, and a dopant dose in the first drain extension subregion located laterally closer to the drain terminal is greater than that in the second drain extension subregion. It is thereby possible to achieve a further improvement in the on resistance Rdson and the drain-to-source blocking capacity, i.e. a drain-to-source breakdown voltage.

The semiconductor device can be used in a multiplicity of applications. In accordance with one embodiment, by way of example, a DC-DC converter comprises one of the above-described embodiments of the semiconductor device.

### BRIEF DESCRIPTION OF THE DRAWINGS

The accompanying drawings serve to afford an understanding of exemplary embodiments of the invention, are included in the disclosure and form part thereof. The drawings merely illustrate exemplary embodiments and together with the description serve to elucidate the latter. Further exemplary embodiments and numerous advantages from among those intended are evident directly from the following detailed description. The elements and structures shown in the drawings are not necessarily illustrated in a manner true to scale with respect to one another. Identical reference signs refer to identical or mutually corresponding elements and structures.

FIG. 1 is a schematic cross-sectional view of a planar field effect transistor comprising a first electrode part acting as a gate electrode, and a second electrode part acting as a field plate, and also a drain extension region.

FIG. 2 is a schematic cross-sectional view of a planar field effect transistor as shown in FIG. 1 in which an STI (Shallow Trench Isolation) region is arranged between the first and second electrode part and the drain extension region.

FIG. 3 is a schematic cross-sectional view of a planar field effect transistor as shown in in FIG. 1 in which a LOCOS (Local Oxidation of Silicon) region is arranged between the first and second electrode part and the drain extension region.

FIG. 4 is a schematic cross-sectional view of a planar field effect transistor as shown in FIG. 1 in which a planar dielectric is arranged between the first and second electrode part and the drain extension region.

FIG. 5 is a schematic cross-sectional view of a planar field effect transistor as shown in FIG. 1 in which a triangular or chamfered dielectric is arranged between the first and second electrode part and the drain extension region.

FIG. 6 is a schematic cross-sectional view of a planar field effect transistor as shown in FIG. 1 in which a field plate effect is realized by both the second electrode part and a contact pad formed above the second electrode part.

FIG. 7 is a schematic cross-sectional view of a planar field effect transistor as shown in FIG. 1 in which the drain extension region is subdivided into differently doped subregions.

FIG. 8 is a schematic cross-sectional view of a planar field effect transistor as shown in FIG. 1 in which a buried body region is subdivided into differently doped subregions.

FIG. 9 is a schematic cross-sectional view of a planar field effect transistor as shown in FIG. 1 in which the second electrode part and also a third electrode part spaced apart laterally act as a field plate.

FIG. 10 is a graph illustrating the temporal profile of gate and drain voltages for different planar field effect transistors.

FIG. 11 shows a schematic circuit diagram of a DC-DC converter comprising field effect transistors which can be fashioned in accordance with the embodiments in FIGS. 1 to 9.

### DETAILED DESCRIPTION

In the following detailed description, reference is made to the accompanying drawings, which form part of the disclosure and show specific exemplary embodiments for illustration purposes. In this context, a direction terminology such as “top side”, “bottom”, “front side”, “rear side”, “at the front”, “at the back”, etc. is related to the orientation of the figures currently being described. Since the component parts of the exemplary embodiments can be positioned in different orientations, the direction terminology is used only for explanation purposes and should in no way be interpreted as limiting.

It goes without saying that further exemplary embodiments exist and structural or logical changes can be made to the exemplary embodiments, without departing in the process from what is defined by the patent claims. The description of the exemplary embodiments is non-limiting in this respect. In particular, elements from exemplary embodiments described below can be combined with elements from other exemplary embodiments from among those described, unless something different is evident from the context.

The terms “have”, “contain”, “encompass”, “comprise” and the like hereinafter are open terms which on the one hand indicate the presence of the stated elements or features, and on the other hand do not exclude the presence of further elements or features. The indefinite articles and the definite articles encompass both the plural and the singular, unless something different is unambiguously evident from the context.

The terms “have”, “contain”, “encompass”, “comprise” and similar terms are open terms, and the terms indicate the presence of the stated structures, elements or features, but do not exclude additional elements or features. The indefinite articles and the definite articles are intended to encompass both the plural and the singular, unless something different is clearly evident from the context.

The term “electrically connected” describes a permanent low-impedance connection between electrically connected elements, for example a direct contact between the relevant elements or a low-impedance connection via a metal and/or a highly doped semiconductor. The term “electrically coupled” encompasses the fact that one or more intervening elements suitable for signal transmission can be present between the electrically coupled elements, for example elements that are controllable in order to provide at times a low-impedance connection in a first state and a high-impedance electrical decoupling in a second state.

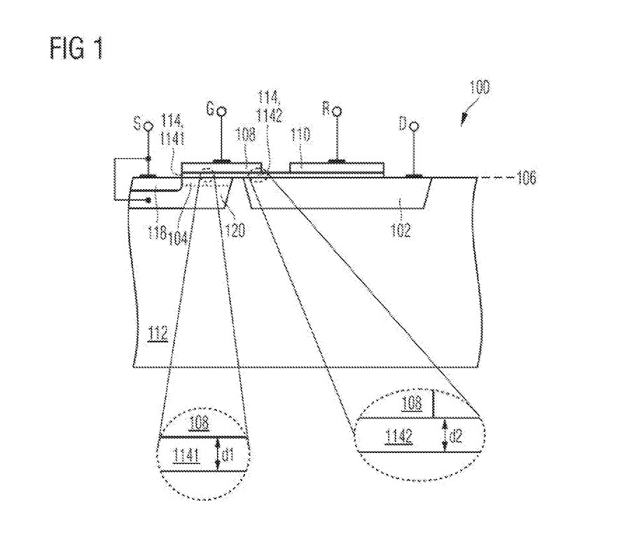

FIG. 1 illustrates one embodiment of a planar field effect transistor 100 in a schematic cross-sectional view. The planar field effect transistor 100 comprises a drain extension region 102 between a channel region 104 and a drain terminal D at a first surface 106 of a semiconductor body 112. The planar field effect transistor additionally comprises a first electrode part 108 and a second electrode part 110. The first electrode part 108 is spaced apart laterally from the second electrode part 110, wherein the first electrode part 108 is arranged as a gate electrode above the channel region 104 and the second electrode part 110 is arranged above the drain extension region 102 and is electrically isolated from the first electrode part 108. The second electrode part 110 acts a field plate and is electrically connected to a reference terminal R, e.g. the source terminal S.

Planar field effect transistor denotes a field effect transistor in which a gate dielectric and a gate electrode are produced using planar technology, such that they are positioned on a semiconductor substrate and, unlike in the case of trench gate structures, are not present in a trench extending into the semiconductor substrate.

Consequently, the planar field effect transistor 100 in FIG. 1 comprises a semiconductor body 112, on which an insulating structure 114 is formed at the first surface 106. The insulating structure 114 comprises a gate dielectric 1141 positioned above the channel region 104 between the first electrode part 108, acting as a gate electrode, and the channel region 104. The insulating structure 114 can comprise further parts in the direction of the drain terminal D, for example, which further parts differ from the gate dielectric 1141 with regard to material composition or geometric dimensions such as thickness. Examples of such further parts of the insulating structure 114 are presented in embodiments described further below. The gate dielectric 1141 can be for example an insulating material such as an oxide, e.g. SiO₂, a nitride, e.g. Si₃N₄, a high-k dielectric or a low-k dielectric or else an arbitrary combination thereof. By way of example, the gate dielectric 1141 is embodied as a thermal oxide. The first electrode part 108 acting as a gate electrode is positioned on the gate dielectric 1141, and is electrically connected to a gate terminal G.

The semiconductor body 112 can be based on various semiconductor materials, such as, for instance, silicon, silicon-on-insulator (SOI), silicon-on-sapphire (SOS), silicon-germanium, germanium, gallium arsenide, silicon carbide, gallium nitride or else further compound semiconductor materials. The semiconductor body can be based on a semiconductor substrate such as, for instance, a semiconductor wafer and comprise one or more epitaxial layers deposited thereon or else be thinned back. A conductivity type of the drain extension region 102 corresponds to a part of the semiconductor body 112 that surrounds the drain extension region 102. However, for example, a doping concentration in the drain extension region 102 can turn out to be comparatively higher.

The planar field effect transistor 100 can be constructed for example from field effect transistor cells embodied in the form of a strip or strip segment. It goes without saying that the field effect transistor cells can also have any other form desired, e.g. be circular, elliptic, polygonal such as octahedral, for instance.

The second electrode part 110 acting as a field plate is electrically connected to a reference potential such as a source terminal S, for instance. The source terminal S is a conductive structure, for example, which can comprise conductive component parts electrically connected to one another such as, for instance, contact plugs, metallization tracks and terminal pads. The conductive component parts in turn consist of conductive material such as, for instance, a metal, a metal silicide, a metal alloy, a highly doped semiconductor or a combination thereof. The indications given for the source terminal S with regard to material and structure are applicable to the drain terminal D.

The source terminal S is electrically connected to a source region 118 of a first conductivity type and electrically connected to a body region 120 of a second conductivity type. The first conductivity type corresponds to the conductivity type of the drain extension region 102. The electrical connection between the body region 120 and the source terminal S is illustrated in a simplified manner in FIG. 1 and can be realized in diverse ways in practice. By way of example, the source terminal S can comprise a trench contact that extends into the semiconductor body 112 and electrically contacts the body region 120 via a bottom of the trench contact and a part of the sidewall. Likewise, the body region 120 can be electrically contacted for example by virtue of the fact that the source region 118 and the body region 120 are led along a direction directed perpendicular to the plane of the drawing in FIG. 1, e.g. along a strip in the case of a strip-shaped configuration of transistor cells of the planar field effect transistor 100, alternately to the first surface 106 and are in electrical contact there with the source terminal S. For this purpose, the source region 118, along a direction directed perpendicular to the plane of the drawing in FIG. 1, is embodied in the form of segments spaced apart from one another between which segments the contact region for the body region 120 is then situated. Moreover, the body region 120 and the source region 118 at the first surface 109 can laterally adjoin one another and each be in electrical contact with the source terminal S.

The planar field effect transistor 100 can be realized for example monolithically using a mixed technology. Such mixed technologies make it possible, in one chip, for example, to form analog blocks by means of the bipolar components contained in this technology for interfaces to digital systems, digital blocks by means of the CMOS (Complementary Metal-Oxide-Semiconductor) components contained in this technology for signal processing, and also high-voltage or power blocks by means of field effect transistors contained in this technology. Such mixed technologies are known for example as bipolar-CMOS-DMOS, BCD technologies or smart power technologies, SPT, and are used in a multiplicity of fields of application in the area of e.g. lighting, motor control, automotive electronics, power management for mobile devices, audio amplifiers, power supply, hard disks, printers.

The drain extension region 102 is a semiconductor region of the first conductivity type that carries away the channel current emerging at the end of the channel region 104 to the drain terminal D. In a manner similar to how a drift zone in a vertical power semiconductor component serves to carry away the channel current in a vertical direction to the drain terminal, the drain extension region 102 serves as a drift zone in which a load current is passed in a lateral direction to the drain terminal D. In a manner similar to the drift zone in vertical power semiconductor components, the drain extension region 102 in the planar field effect transistor also makes a significant contribution to the blocking capability of these components, i.e. the maximum drain-to-source voltage during operation, which is typically specified in the data sheet of the components. Said blocking capability can be influenced and suitably set by means of suitable dimensioning and doping of the drain extension region 102 for example. In one embodiment, the drain extension region 102 is suitable for blocking a drain-to-source voltage in a range of 5 V to 200 V.

In one embodiment, the gate dielectric 1141 is embodied as a part of the insulating structure 114 between the channel region 104 and the first electrode part 108. The insulating structure 104 also comprises a further dielectric 1142 formed, inter alia, between the first electrode part 108 and the drain extension region 102, wherein a thickness d2 of the further dielectric 1142 is greater than a thickness d1 of the gate dielectric 1141. The gate dielectric 1141 adjoins the further dielectric 1142 in the direction of the drain terminal D. The further dielectric 1142 can, for example, consist of or comprise one or a combination of the dielectrics STI (Shallow Trench Isolation), LOCOS (Local Oxidation of Silicon), planar dielectric, chamfered dielectric.

By way of example, in order to produce the insulating structure, it is possible to have recourse to the different dielectrics fabricated using a mixed technology and to combine these or some of these dielectrics to form the insulating structure 114.

One embodiment relates to the planar field effect transistor shown in FIG. 1 in which the reference terminal R of the second electrode part 110 is electrically connected to the source terminal.

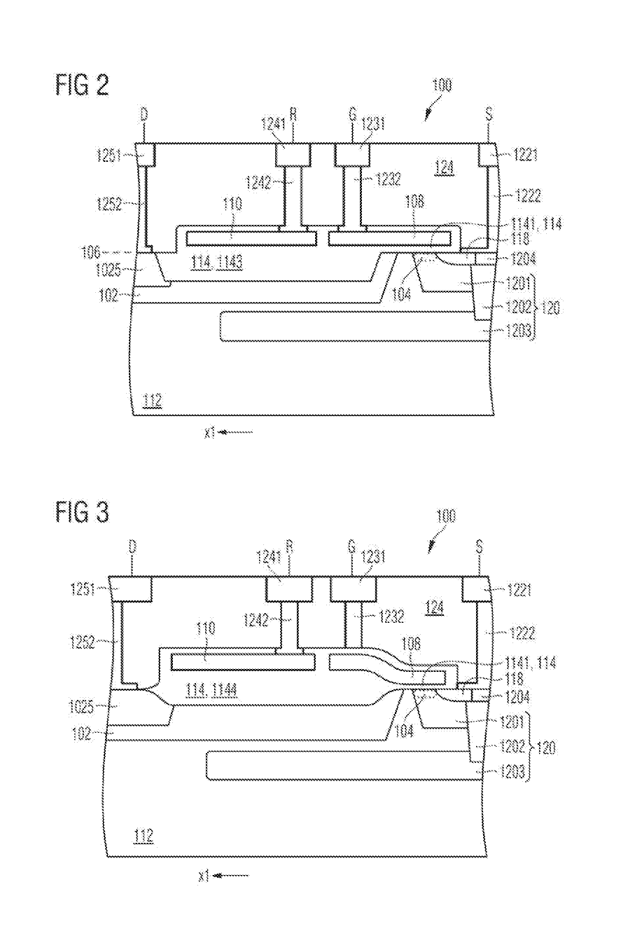

The cross-sectional view of a planar field effect transistor 100 as shown in FIG. 2 illustrates one embodiment in which the body region 120 comprises first, second and third body subregions 1201, 1202, 1203 of the second conductivity type. The first body subregion 1201 adjoins the gate dielectric 1141 and thus serves for forming a conductive channel when a suitable voltage is applied to the first electrode part 108 acting as a gate electrode. The second body subregion 1202 serves as a vertical terminal region for a buried third body subregion 1203, which extends laterally as a deep body subregion below the drain extension region 102, wherein an extent of the deep body subregion 1083 in a first lateral direction x1 and an extent of the drain extension region 102 in the first lateral direction x1 at least partly overlap. The partial overlap has a positive effect on the blocking capability of the planar field effect transistor 100 on account of the compensation principle or RESURF (REduced SURface Field) principle. The extent of the third body subregion 1203 in the first lateral direction x1 and an extent of the first electrode part 108 in the first lateral direction x1 partly overlap.

Depending on whether the doping of the second body subregion 1202 at the first surface 106 is suitable for forming an ohmic contact, a highly doped body terminal region 1204 of the second conductivity type can be formed at the first surface 106 in order to electrically connect the first to third body subregions 1201, 1202, 1203 to the source terminal S. Besides the body region 120, the source region 118 is also electrically connected to the source terminal S. The electrical connection of body region 120 and source region 118 at the first surface 106 can be effected in diverse ways. In this context, reference is made to the explanations further above.

The source terminal S comprises a first contact pad 1221, e.g. a part of a wiring plane, such as a metallization plane, and a first electrical contact 1222, wherein the first electrical contact 1221 extends through an intermediate dielectric 124 to the body region 120 or the source region 118 and makes electrical contact therewith. The gate terminal comprises a second contact pad 1231, e.g. a part of a wiring plane, such as a metallization plane, and a second electrical contact 1232, wherein the second electrical contact 1231 extends through the intermediate dielectric 124 to the first electrode part 108 and makes electrical contact therewith. A reference electrode R comprises a third contact pad 1241, e.g. a part of a wiring plane, such as a metallization plane, and a third electrical contact 1242, wherein the third electrical contact 1241 extends through the intermediate dielectric 124 to the second electrode part 110 acting as a field plate and makes electrical contact therewith. The source terminal S and the reference electrode R can be short-circuited, for example. The drain terminal D comprises a fourth contact pad 1251, e.g. a part of a wiring plane, such as a metallization plane, and a fourth electrical contact 1252, wherein the forth electrical contact 1252 extends through the intermediate dielectric 124 to the body region 120 or the drain terminal region 1025 and makes electrical contact therewith. The first to fourth contact pads 1222, 1232, 1242, 1252 can be produced for example from the same wiring plane by means of lithographic patterning into the different contact pads. Likewise, the first to fourth electrical contacts 1221, 1231, 1241, 1251 can be processed for example jointly as contact plugs or contact series.

The first electrode part 108 acting as a gate electrode extends along the first lateral direction x1 beyond the termination of the first body subregion 1201 and overlaps the drain extension region 102. Between the drain extension region 102 and the first electrode part 108, an STI region 1143 is formed as part of the insulating structure 114. The STI region 1143 is likewise formed between the second electrode part 110 and the drain extension region 102. The second electrode part 110 that is electrically isolated from the gate terminal G acts as a field plate and promotes the blocking capability of the planar field effect transistor 100. The drain extension region 102 is electrically connected to the drain terminal D via the drain terminal region 1025, e.g. a highly doped region of the first conductivity type.

In the embodiment shown in FIG. 2, the gate dielectric 1141 continues laterally by way of the channel region 114 in the direction of the drain terminal D and then transitions into the STI region 1143 of the insulating structure 114 below the first electrode part 108.

By virtue of the separation of the second electrode part 110 acting as a field plate from the gate terminal G and as a result of the configuration of the insulating structure 114, the embodiment shown in FIG. 2 makes it possible to reduce the gate capacitance and thus to lower the switching losses in the medium and low current ranges of circuit applications of the planar field effect transistor 100.

FIG. 3 illustrates a further embodiment of the planar field effect transistor 100 in a cross-sectional view. Features of this embodiment which correspond or are similar to those of the embodiment shown in FIG. 2 are provided with corresponding reference signs. The embodiment shown in FIG. 3 differs from the embodiment in FIG. 2 in that the insulating structure 114 for reducing the electric field at the first surface comprises, instead of the STI region 1143, a LOCOS region 1144 which, on account of the processing of this oxide, both extends into the semiconductor body 112 and is formed above the latter. Consequently, the first electrode part 108 also extends obliquely in the transition region from the gate dielectric 1141 to the LOCOS region 1144.

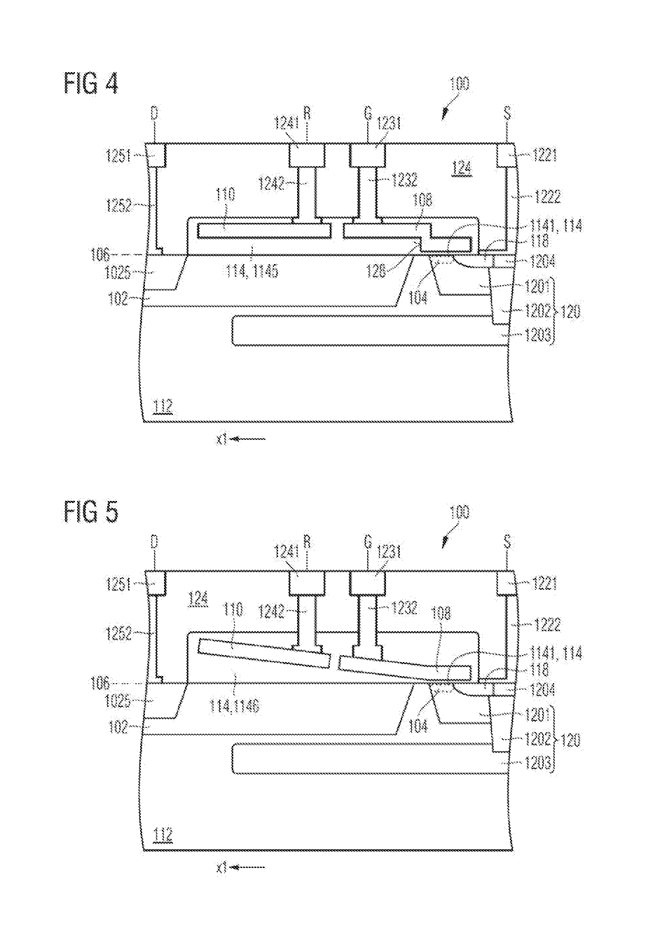

FIG. 4 illustrates a further embodiment of the planar field effect transistor 100 in a cross-sectional view. Features of this embodiment which correspond or are similar to those of the embodiment shown in FIG. 2 are provided with corresponding reference signs. The embodiment shown in FIG. 4 differs from the embodiment in FIG. 2 in that the insulating structure 114 for reducing the electric field at the first surface 106 comprises, instead of the STI region 1143 a planar dielectric 1145 such as a planar oxide, for instance, the top side of which transitions into a top side of the gate dielectric 1141 via a step 128 directed toward the first surface 106.

FIG. 5 illustrates a further embodiment of the planar field effect transistor 100 in a cross-sectional view. Features of this embodiment which correspond or are similar to those of the embodiment shown in FIG. 2 are provided with corresponding reference signs. The embodiment shown in FIG. 5 differs from the embodiment in FIG. 2 in that the insulating structure 114 for reducing the electric field at the first surface comprises, instead of the STI region 1143 a triangular dielectric 1146, wherein a thickness of the triangular dielectric 1146 increases in the direction of the drain terminal D, an underside of the triangular dielectric 1146 extends parallel to the first surface 106, and the second electrode part 110 is arranged on a top side region of the triangular dielectric 1146 that is oblique with respect to the first surface 106.

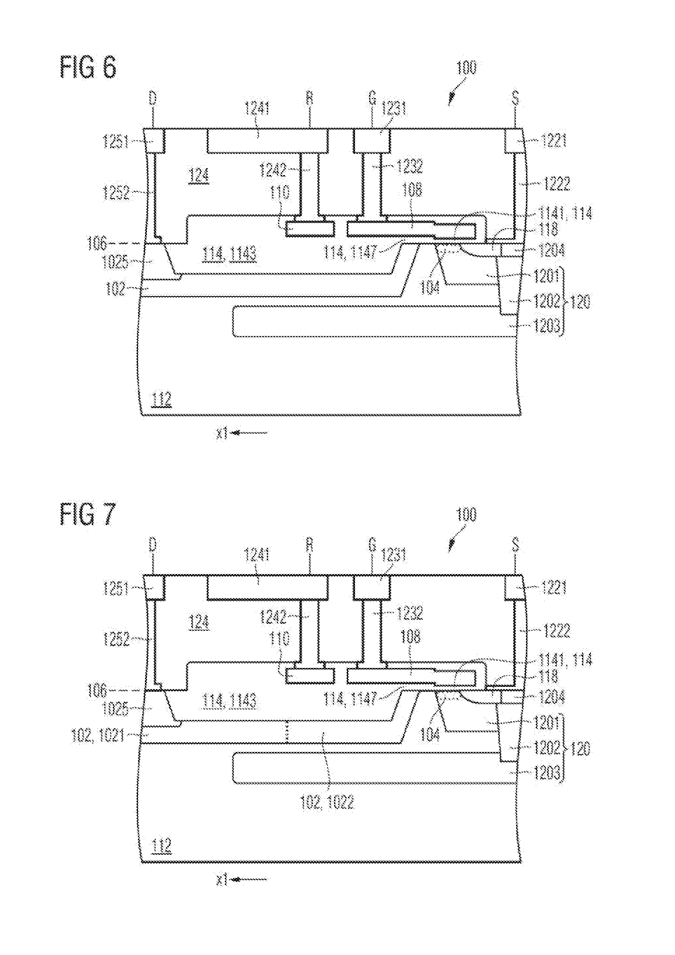

FIG. 6 illustrates a further embodiment of the planar field effect transistor 100 in a cross-sectional view. Features of this embodiment which correspond or are similar to those of the embodiment shown in FIG. 2 are provided with corresponding reference signs. The embodiment shown in FIG. 6 differs from the embodiment in FIG. 2 by virtue of the fact that, in order to further improve the blocking capacity between drain and source, the field plate is formed not only by the second electrode part 110, which is laterally shortened by comparison with the embodiment from FIG. 2, but additionally by the third contact pad 1241. Furthermore, a further planar dielectric 1147 is formed between the STI region 1143 and the gate dielectric 1141, said further planar dielectric being thicker than the gate dielectric 1141 and thereby contributing to further reduction of the gate capacitance.

FIG. 7 illustrates a further embodiment of the planar field effect transistor 100 in a cross-sectional view. Features of this embodiment which correspond or are similar to those of the embodiment shown in FIG. 6 are provided with corresponding reference signs. The embodiment shown in FIG. 7 differs from the embodiment in FIG. 6 by virtue of the fact that the drain extension region comprises laterally adjacent first and second drain extension subregions 1021, 1022, and a dopant dose in the first drain extension subregion 1021 located laterally closer to the drain terminal D is greater than in the second drain extension subregion 1022. As a result, it is possible to achieve a further improvement in the on resistance and the drain-source blocking capacity.

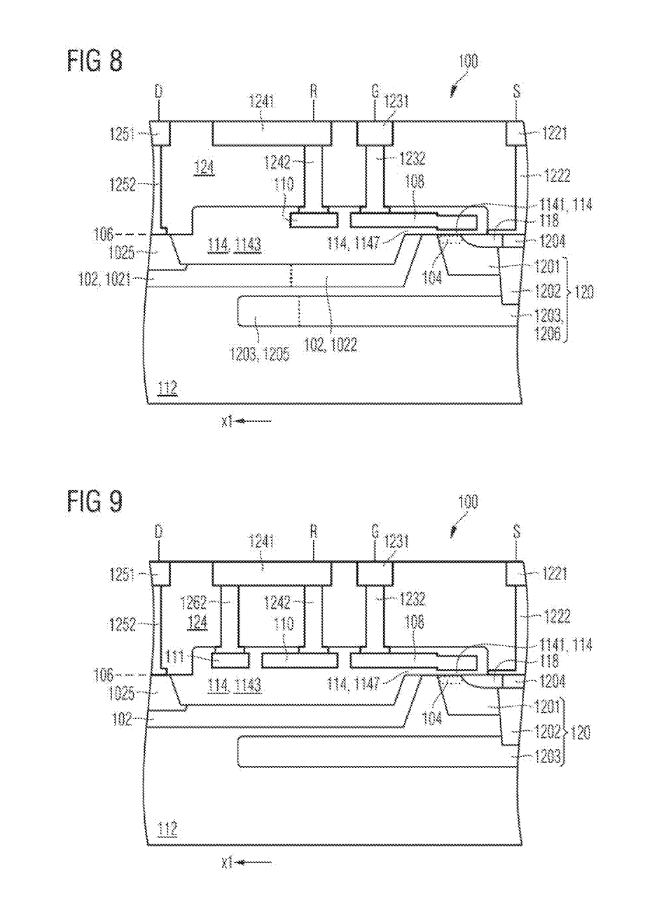

FIG. 8 illustrates a further embodiment of the planar field effect transistor 100 in a cross-sectional view. Features of this embodiment which correspond or are similar to those of the embodiment shown in FIG. 7 are provided with corresponding reference signs. The embodiment shown in FIG. 8 differs from the embodiment in FIG. 7 in that the third body subregion 1203 comprises adjacent first and second body partial regions 1205, 1206, and a dopant dose in the first body partial region 1205 located laterally closer to the drain terminal D is less than that in the second body partial region 1206. As a result, it is possible to achieve a further improvement in the on resistance and the drain-source blocking capacity.

FIG. 9 illustrates a further embodiment of the planar field effect transistor 100 in a cross-sectional view. Features of this embodiment which correspond or are similar to those of the embodiment shown in FIG. 7 are provided with corresponding reference signs. The embodiment shown in FIG. 9 differs from the embodiment in FIG. 7 by a third electrode part 111 above the drain extension region 102, wherein the second electrode part 110 is arranged laterally between the third electrode part 111 and the first electrode part 108. The third electrode part 111 is electrically connected to the second electrode part 110 via a fifth electrical contact 1262, the third contact pad 1241 and the third electrical contact 1242. As a result, it is possible to achieve a further improvement in the on resistance and the drain-source blocking capacity.

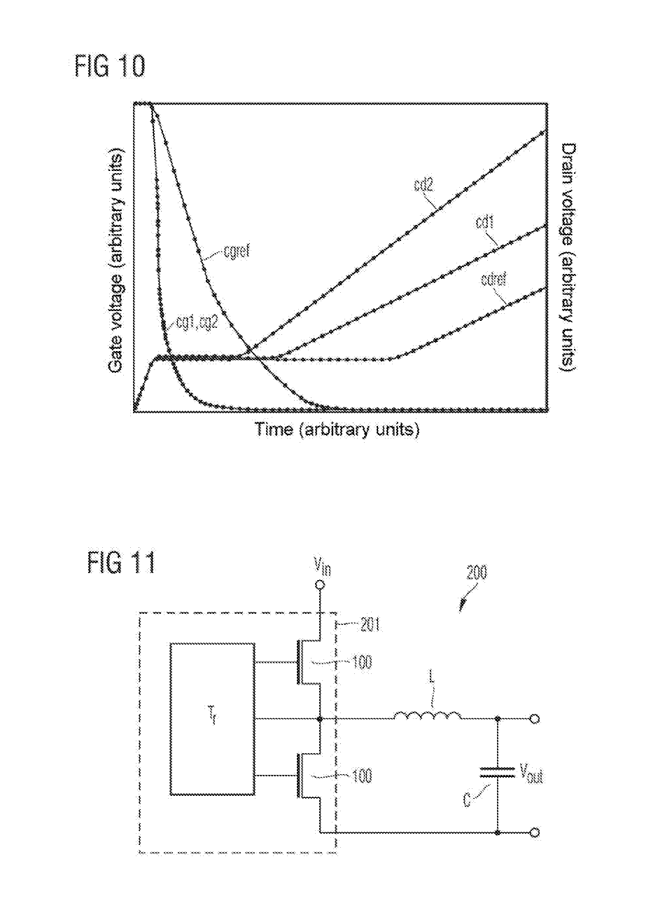

FIG. 10 illustrates a schematic graph, the left-hand y-axis of which relates to a gate voltage and the right-hand y-axis of which relates to a drain voltage. The curves illustrated relate to the simulated temporal profile of these voltages for a constant gate current. As a planar reference field effect transistor, use is made of a field effect transistor which comprises no second electrode part as shown in FIG. 1 and the gate dielectric of which is laterally adjacent to an STI region. The curves cgref and cdref show the temporal profile of the gate and drain voltages. The curves cg1 and cd1 show the temporal profile of the gate and drain voltages of an embodiment as shown in FIG. 2 in which a second field electrode part 110 acting as a field electrode is present besides the first electrode part 108 acting as a gate electrode. Comparison of the curves cg1 and cd1 with the curves cgref and cdref reveals the advantageous reduction of the charge duration of the gate-drain capacitance. A further improvement can be achieved by positioning between the gate dielectric 1141 and the STI region 1143 in the embodiment from FIG. 2 a further planar dielectric, which is thicker in comparison with the thickness of the gate dielectric 1141, cf. for instance the further planar dielectric 1147 in the embodiment from FIG. 6. This further improvement is evident upon comparison of the curves cg2 and cd2 with the curves cg1 and cd1.

The schematic diagram in FIG. 11 shows an application example in the form of a DC-DC converter 200, in which the planar field effect transistor 100 can be embodied. The DC-DC converter 200 additionally comprises a driver stage Tr and converts an input voltage Vin into an output voltage Vout by means of the planar field effect transistor 100 and a downstream filter comprising a coil L and a capacitator C. The elements contained within the region 201 illustrated by dashed lines can be embodied for example as an integrated circuit.

Although specific embodiments have been illustrated and described herein, those skilled in the art will recognize that the specific embodiments shown and described can be replaced by a multiplicity of alternative and/or equivalent configurations, without departing from the scope of protection of the invention. The application is intended to cover any adaptations or variations of the specific embodiments discussed herein. Therefore, the invention is restricted only by the claims and the equivalents thereof.

What is claimed is:

1. A planar field effect transistor, comprising:
a drain extension region between a channel region and a drain terminal at a first surface of a semiconductor body; and
a first electrode part and a second electrode part laterally spaced apart from the first electrode part, the first electrode part being arranged as a gate electrode above the channel region, the second electrode part being arranged above the drain extension region and electrically isolated from the first electrode part.

2. The planar field effect transistor of claim 1, wherein the second electrode part is electrically connected to a source terminal.

3. The planar field effect transistor of claim 1, wherein the planar field effect transistor is a lateral power semiconductor component in which a body region and a source region are electrically short-circuited.

4. The planar field effect transistor of claim 1, wherein the drain extension region is configured to block a drain-to-source voltage in a range of 5V to 200V.

5. The planar field effect transistor of claim 1, wherein the first electrode part and the second electrode part are different parts of a patterned electrode layer.

6. The planar field effect transistor of claim 1, further comprising:
a deep body region electrically connected to a source terminal and extending laterally below the drain extension region,
wherein the deep body region and the drain extension region at least partly overlap in a first lateral direction.

7. The planar field effect transistor of claim 6, wherein the deep body region and the second electrode part at least partly overlap in the first lateral direction.

8. The planar field effect transistor of claim 6, wherein the deep body region comprises laterally adjacent first and second body partial regions, and wherein a dopant dose in the first body partial region located laterally closer to the drain terminal is lower than a dopant dose in the second body partial region.

9. The planar field effect transistor of claim 1, further comprising:
a gate dielectric between the first electrode part and the channel region; and
a further dielectric between the first electrode part and the drain extension region,
wherein a thickness of the further dielectric is greater than a thickness of the gate dielectric,
wherein the gate dielectric adjoins the further dielectric in a direction of the drain terminal.

10. The planar field effect transistor of claim 9, wherein the further dielectric comprises a shallow trench isolation dielectric.

11. The planar field effect transistor of claim 10, wherein between the STI dielectric and the gate dielectric the further dielectric comprises a planar dielectric that is thicker than the gate dielectric and at the first surface adjoins a top side of a part of the drain extension region.

12. The planar field effect transistor of claim 9, wherein a part of the gate dielectric at the first surface adjoins a top side of a part of the drain extension region.

13. The planar field effect transistor of claim 9, wherein the further dielectric is a LOCOS (Local Oxidation of Silicon) oxide.

14. The planar field effect transistor of claim 9, wherein the further dielectric is a planar dielectric, wherein an underside of the planar dielectric transitions into an underside of the gate dielectric without any steps, and wherein a top side of the planar dielectric transitions into a top side of the gate dielectric via a step directed toward the first surface.

15. The planar field effect transistor of claim 9, wherein a thickness of the further dielectric increases in a direction of the drain terminal, wherein an underside of the further dielectric extends parallel to the first surface, and wherein the second electrode part is arranged on a top side region of the further dielectric that is oblique with respect to the first surface.

16. The planar field effect transistor of claim 1, wherein the second electrode part is electrically connected via a contact to a field plate arranged above the second electrode part, and wherein the field plate extends in a lateral direction further to the drain terminal than the second electrode part.

17. The planar field effect transistor of claim 1, further comprising:
a third electrode part above the drain extension region,
wherein the second electrode part is arranged laterally between the third electrode part and the first electrode part,
wherein the third electrode part is electrically connected to the second electrode part via a field plate.

18. The planar field effect transistor of claim 1, wherein the drain extension region comprises laterally adjacent first and second drain extension subregions, and wherein a dopant dose in the first drain extension subregion located laterally closer to the drain terminal is greater than a dopant dose in the second drain extension subregion.

19. A DC-DC converter comprising the planar field effect transistor of claim 1.
